(19) United States
(12) Patent Application Publication
(10) Pub. No.: US 2005/0241803 A1
(43) Pub. Date: Nov. 3, 2005

(54) Liquid cooling loop using tubing and bellows for stress isolation and tolerance variation

(75) Inventors: Christopher G. Malone, Loomis, CA (US); Glenn C. Simon, Auburn, CA (US); Stephan K. Barsun, Sacramento, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 10/837,466

(22) Filed: Apr. 29, 2004

(51) Int. Cl. H05K 7/20

(52) U.S. Cl. 165/80.4; 361/699

(57) ABSTRACT

A liquid loop cooling apparatus includes rigid or semi-rigid tubing enclosing an interior bore or lumen within which a cooling fluid can circulate among at least one heat-generating component in a closed-loop system. The liquid loop cooling apparatus also includes at least one flexible bellows coupled to the tubing that isolates physical stresses along the tubing.

### BACKGROUND OF THE INVENTION

Electronic systems and equipment such as computer systems, network interfaces, storage systems, and telecommunications equipment are commonly enclosed within a chassis, cabinet or housing for support, physical security, and efficient usage of space. Electronic equipment contained within the enclosure generates a significant amount of heat. Thermal damage may occur to the electronic equipment unless the heat is removed.

Compact electronic systems and devices, for example compact computer servers, often have very little space available for implementing a cooling solution. Conventional air-cooled heat sinks generally must be directly connected to the heat source. The footprint of the heat sink cannot be much larger than the heat source given the intrinsic heat spreading resistance of an aluminum or copper heat sink. Given the restriction on heat sink height dictated by the form factor and the practical limits on heat sink footprint, cooling capabilities are highly restricted.

### SUMMARY

In accordance with a cooling device embodiment, a liquid loop cooling apparatus includes rigid or semi-rigid tubing enclosing an interior bore or lumen within which a cooling fluid can circulate among at least one heat-generating component in a closed-loop system. The liquid loop cooling apparatus also includes at least one flexible bellows coupled to the tubing that isolates physical stresses along the tubing.

### BRIEF DESCRIPTION OF THE DRAWINGS

Embodiments of the invention relating to both structure and method of operation, may best be understood by referring to the following description and accompanying drawings.

FIGS. 1A and 1B are perspective pictorial diagrams illustrating embodiments of liquid loop cooling systems that include a bellows for stress isolation and tolerance variation.

FIGS. 2A-2E are perspective pictorial views showing various embodiments of bellows that are suitable for usage in a liquid loop cooling apparatus.

FIGS. 3A and 3B show a perspective pictorial diagram and an overhead pictorial view illustrating embodiments of an electronic system with a liquid loop cooling system using flexible bellows for isolation and tolerance variation.

### DETAILED DESCRIPTION

Future electronic system architectures, such as compact server architectures, may use a liquid loop cooling solution to accommodate increasing power and heat flux levels of microprocessors and associated electronics. A liquid loop system may have a pump to drive cooling fluid through cold plates attached to processors and other high-power components, and drive the fluid along tubes completing a loop between a cold plate, a heat exchanger, and the pump. Heat is removed from the loop by forced-air convection at the heat exchanger.

A flexible bellows can be included in the liquid loop to flexibly couple components that make up the cooling loop to reduce stress on the system.

A liquid cooling loop, such as a single-phase loop, may include some or all of several components and devices. For example, the loop may include components such as one or more cold plates, a pump, a liquid-to-air heat exchanger, and possibly an accumulator or reservoir. The components are connected to one another by rigid or semi-rigid tubing to create a closed-loop system. Because the tubing connecting the components has rigidity, several difficulties can occur. Vibration from the pump can disturb the cold plate attachment to a heat-dissipating device. Other sources of shock and vibration, such as occurs during transportation, can cause damage to one or more components in the system. Expansion and contraction due to temperature changes can induce high stresses if components are rigidly attached. Also, dimensional variation due to manufacturing tolerances can cause fit problems or lead to excessive stress during system assembly.

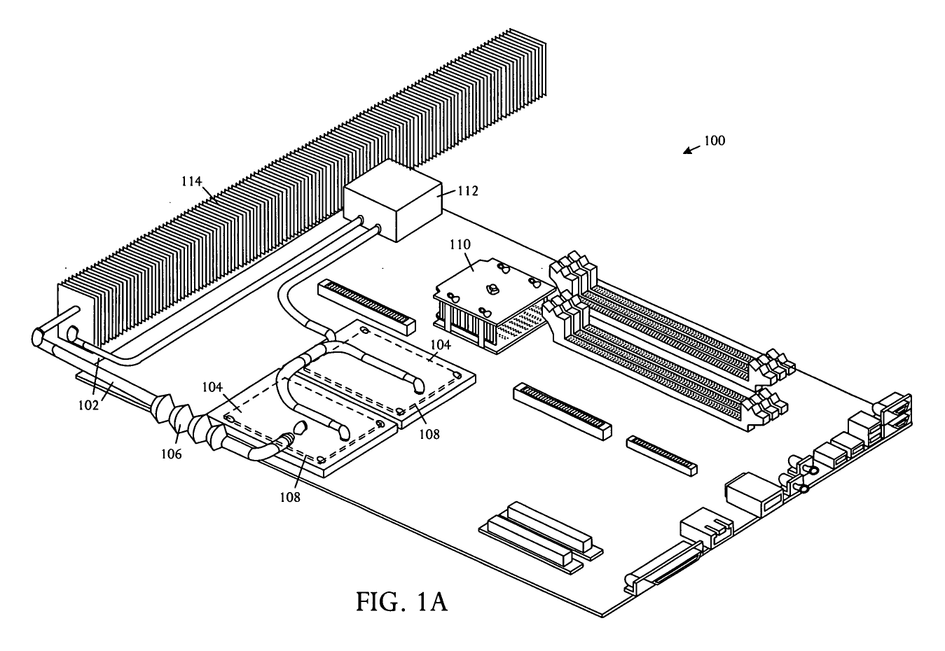

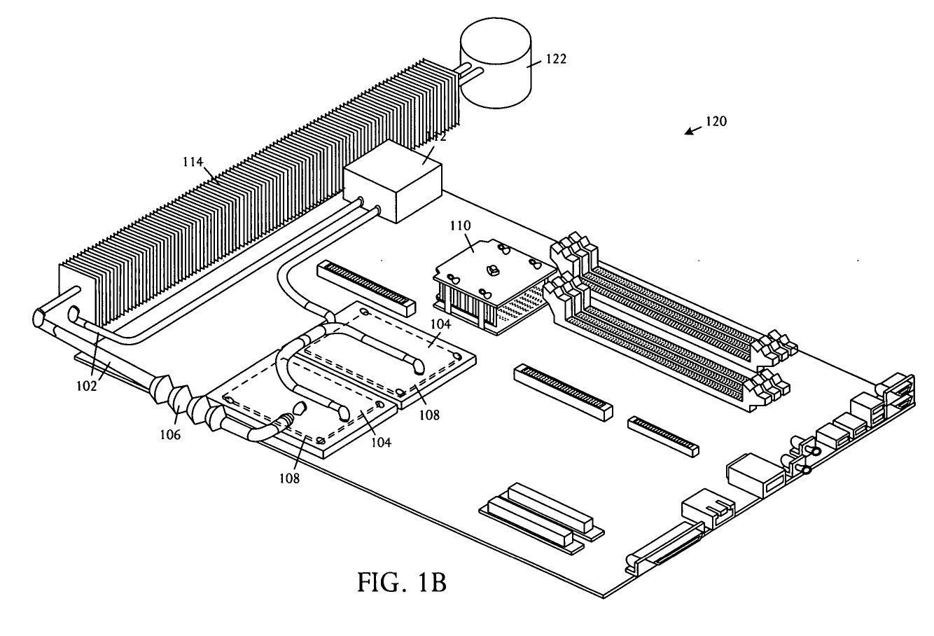

Referring to FIG. 1A, a perspective pictorial diagram illustrates an embodiment of a liquid loop cooling apparatus 100. The liquid loop cooling apparatus 100 includes a rigid or semi-rigid tubing 102 enclosing an interior bore or lumen within which a cooling fluid can circulate among at least one heat-generating component 104 in a closed-loop system. The liquid loop cooling apparatus 100 also includes at least one flexible bellows 106 coupled to the tubing 102 that isolates physical stresses along the tubing.

The flexible bellows 106 is incorporated into the tubing 102 connecting the various components of the liquid cooling loop 100, thus flexibly mechanically isolating each part of the liquid loop system from the other parts.

The liquid loop cooling apparatus 100 circulates coolant through a closed loop that contains components and devices for flow control, heat absorption, and heat removal. Tubing 102, for example constructed from various plastics or metals, makes up the cooling loop generally arranged in multiple branches using various disconnect elements, and three-way tee or four-way cross junctions.

The bellows can be constructed from various plastic, rubber, various metals, and the like, depending on construction characteristics of the liquid loop.

At least one component 104, shown in dashed lines illustrating that the component 104 is contained beneath a cold plate 108, is rigidly coupled to the tubing 102. The flexible bellows 106 connects to the rigid coupling to flexibly and mechanically isolate parts of the rigid or semi-rigid liquid loop cooling apparatus 100 from the other parts.

Associated with some or all components 104, particularly heat-generating components, may be one or more cold plates 108 or heat sinks 110 that promote localized cooling of heat sources by transferring heat to coolant within the tubing 102. A cold plate 108 is typically implemented to cover a heat-dissipating component. A cold plate 108 includes a metal plate with embedded passages for carrying the circulating coolant fluid. Flow distribution within the passages can create a uniform cooling over the cold plate surface.

Examples of cooling elements within a cold plate 108 include cooling elements with a serpentine pattern of cooling liquid-carrying tubules or a manifold with narrow liquid-carrying passages. Liquid circulating through the cold plate 108 creates a cooling effect that dissipates heat generated by the component 104. The cold plate 108 may efficiently transfer thermal energy by forced single-phase liquid convective cooling, by changes in phase such as evaporative cooling, or the like.

One example of a suitable cold plate 108 is a tubed-flow cold plate that generally uses a copper or stainless steel tube pressed into a channeled aluminum extrusion. An increasing number of loops in the cold plate passage improves cold plate performance. Another cold plate example is a distributed-flow cold plate wherein liquid flow is distributed within the cold plate 108. A distributed-flow cold plate may include cross-flow tubes embedded in a solid block of a cold plate. Cross-flow tubes are joined to main tubes to form a U- or Z-flow path configuration. Alternatively, cross-flow passages can be created by joining an extruded aluminum block with microchannels coupled to collector tubes. Some cold plates may include fins brazed into a cavity within the cold plate. Performance of the distributed-flow cold plate varies with uniformity of flow distribution within the plate.

In some embodiments, the liquid loop cooling apparatus 100 may further include a pump 112 coupled to the tubing 102 that is capable of generating a pressure head suitable to drive a cooling fluid interior to the tubing 102 through the loop. Some embodiments may omit the pump 112. For example the fluid motion may be gravity-aided or a wick structure in the tubing to drive the fluid. The one or more cold plates 108 coupled to the tubing 102 are typically positioned near heat-generating components 104 to supply local cooling.

Another optional element of the liquid loop cooling apparatus 100 is a liquid-to-air heat exchanger 114 that can be coupled to the tubing 102 to enable removal of heat absorbed by the coolant as the fluid circulates within the coolant loop.

Referring to FIG. 1B, a perspective pictorial view shows an alternative embodiment of a liquid loop cooling apparatus 120 that further includes a reservoir 122 coupled to the tubing 102. The reservoir 122 can accumulate cooling fluid.

The liquid loop cooling apparatus 100 uses the one or more pumps 112 in combination with the reservoir 122 to circulate flow through the loop. The liquid reservoir 122 maintains system pressure and compensates for any possible leakage. The coolant loop may further include a filter to remove particulates from the circulating coolant. A reservoir 122 can be used on the low pressure/suction side of a pump 112 to maintain a source of fluid to the system.

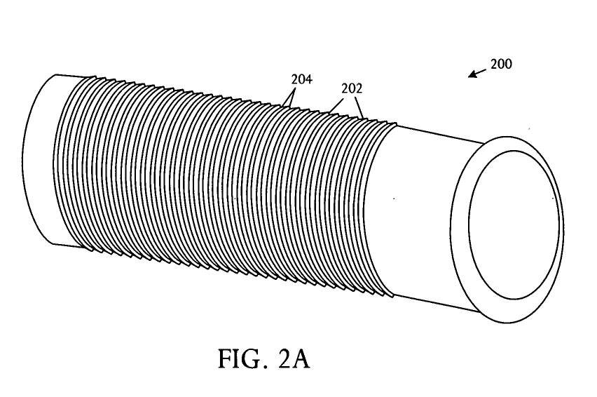

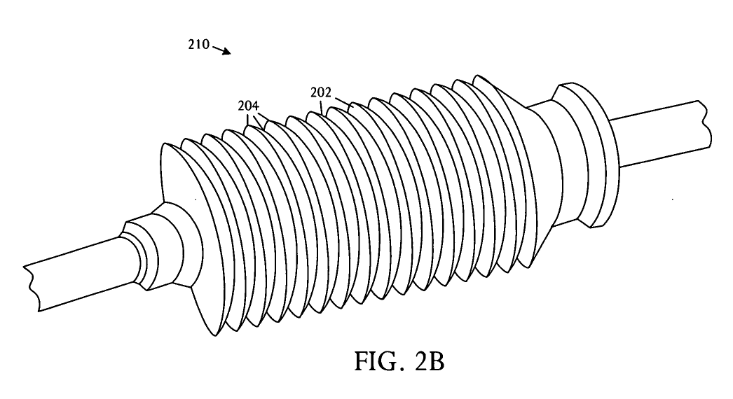

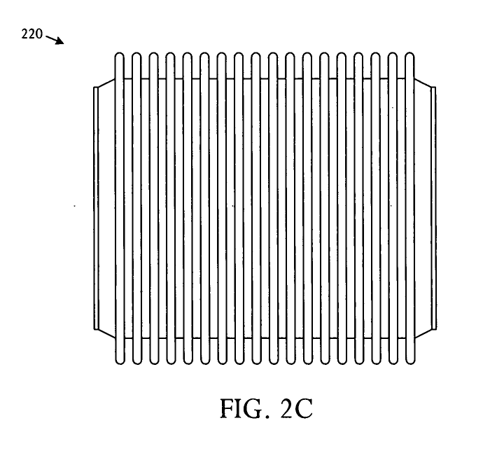

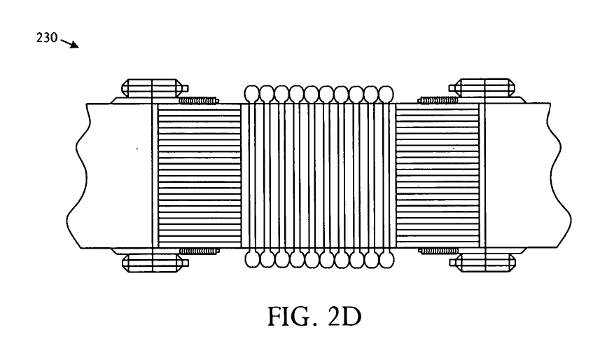

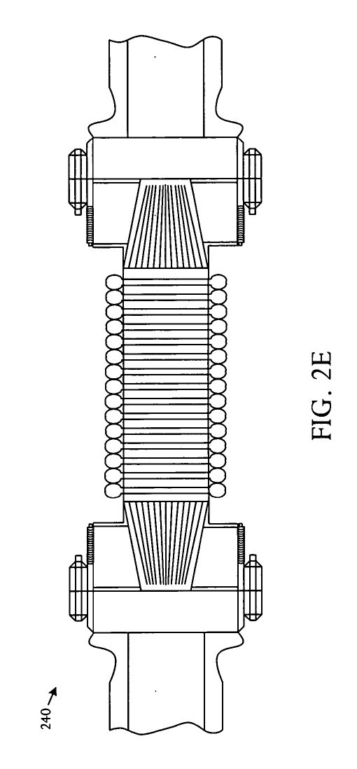

Referring to FIGS. 2A-2E, several perspective pictorial views show embodiments of bellows that are suitable for usage in a liquid loop cooling apparatus.

FIG. 2A shows a flexible bellows connector 200 for usage between two rigid members. The bellows 200 can be used as dampening devices, expansion joints, shielding devices, and the like. The illustrative bellows 200 is capable of various deflections including lateral, axial, and/or angular deflection. The bellows 200 includes multiple web portions 202, the relatively flat part of each folded section, and the hinge 204, the space between the webs 202 that enables the bellows 200 to fold flat and stretch. The bellows 200 has relatively large number of relatively short web portions 202 so that the bellows 200 maintains a generally regular shape during flexure at the expense of some limitation of motion.

The bellows 200 may be constructed from various materials including plastics, such as neoprene, or other elastomers. Other suitable materials include neoprene or polyvinyl chloride (PVC) coated fabrics, glass cloths coated with aluminum or silicone rubber.

FIG. 2B shows an alternative example of a suitable bellows 210. Any suitable type of bellows can be used in the liquid loop cooling system. The web 202 for the bellows 210 has a flat shape profile, enabling long-stroke capability, stroke linearity with pressure and suitable resistance to pressure. The web portion 202 of the bellows 210 is relatively longer than the web for the bellows 200 shown in FIG. 2A, for many materials enabling a wider range of motion.

FIG. 2C illustrates an example of a bellows 220 with a flat cantilever shape profile that gives a constant effective area, resulting in a force output that is linear with pressure.

Various types of bellows can be used including single-ply and multiple-ply bellows. In some cases, multiple-ply bellows are desired since the spring rate of the bellows is proportional to the cube of the wall thickness. Accordingly, multiple-ply construction is useful for high-pressure conditions due to a greater flexibility than a single-ply form with an equivalent total wall thickness.

The spring rate of a bellows varies according to diameter, wall thickness, the number of convolutions, and the material of construction. Flexibility is the deflection of each convolution per change in pressure. Elastic imperfections can be reduced or minimized by using the bellows in combination with a spring with a spring rate higher than that of the bellows.

In some applications, highly-flexible bellows are desired and obtained by configuring the bellows with deeper convolutions, resulting in increased deflection during flexure while spring rate and maximum working pressure are relatively reduced.

Some bellows are heat treated at low temperatures for stress relief annealing, increasing spring rate while stabilizing the material and reducing creep, drift, and hysteresis.

The bellows is generally used in compression at maximum pressures suitably limited to prevent permanent distortion and/or alteration of structural characteristics. Mechanical stops or spring retainers can be used to avoid the possibility of overcompression. Bellows that are substantially longer than the axial outside diameter may risk axial distortion even in pressures lower than the maximum ratings.

FIGS. 2D and 2E depict alternative examples of bellows 230 and 240, respectively, in the form of toroidal bellows. Toroidal bellows are highly useful for high pressures while maintaining a constant effective area and high spring rate.

Various types of bellows may be constructed by edge-welding, forming, and deposition. An edge-welded metal bellows includes convolutions formed by welding individually stamped annular diagrams at inner and outer edges.

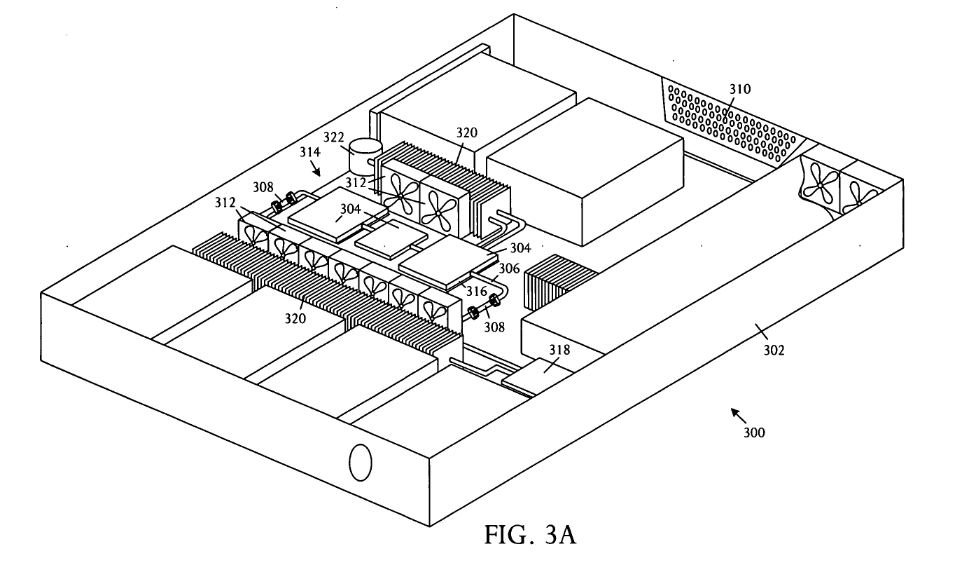

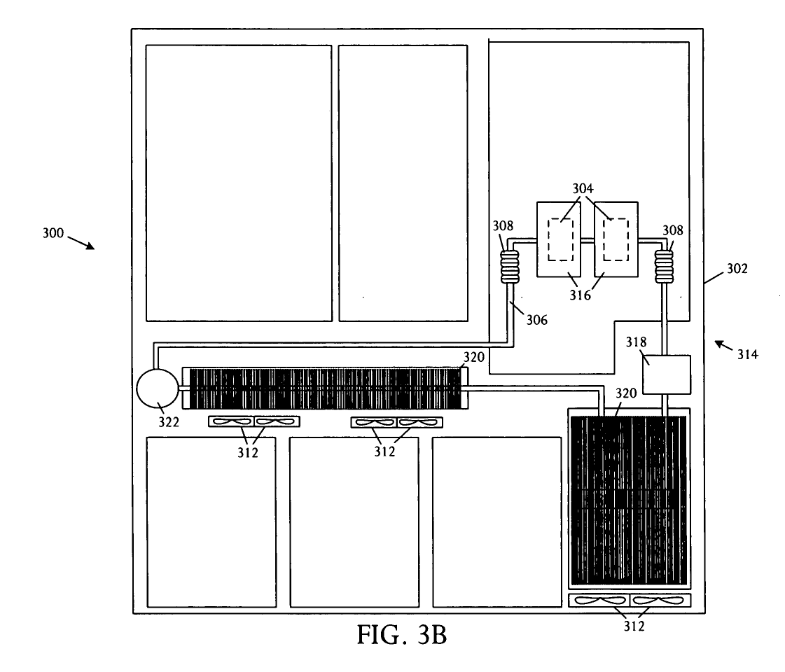

Referring to FIGS. 3A and 3B, a perspective pictorial diagram and an overhead pictorial view illustrate embodiments of an electronic system 300, such as a computer server, that comprises a chassis 302, a plurality of components 304 mounted within the chassis 302 including at least one heat-generating component. A rigid or semi-rigid tubing 306 enclosing an interior bore contains a cooling fluid that circulates among the components 304 in a closed-loop system. One or more flexible bellows 308 are coupled to the tubing and isolate physical stresses along the tubing.

The bellows 308 can be implemented in one tube of the liquid loop. Bellows 308 can be used on one or more of the other tubing legs, depending on the circumstances of mechanical isolation.

Typically one or more components 304 are rigidly coupled to the tubing 306 and the one or more flexible bellows 308 are inserted at selected locations along the tubing 302 to flexibly and mechanically isolate parts of the rigid or semi-rigid liquid loop cooling apparatus from the other parts.

In some embodiments, the electronic system 300 is efficiently sized into a relatively small package, for example with the chassis 302 configured as a compact form factor chassis. Common compact sizes are of the order of 1U or 2U form factors.

In some embodiments, the electronic system 300 has airflow inlet and outlet vents 310 in the chassis 302 and at least one fan 312 capable of circulating air from the inlet vents to the outlet vents 310.

The tubing 306 and bellows 308 form part of a liquid loop cooling system 314 that may take various forms and include various types of devices and components. The liquid loop cooling system 314 may have one or more cold plates 316 coupled to the tubing 306 and arranged to dissipate heat from a heat-generating component of components 304.

In some embodiments, a pump 318 can be coupled to the tubing 306 to assist in circulating cooling fluid through the liquid loop 314. In other embodiments, a pump may be omitted, for example using gravity-assistance or a wick structure in the tubing to facilitate fluid flow. For example, pumping action can be gained using a two-phase heat-transport device that exploits surface tension forces induced in a fine pore wick under heat application to drive a working fluid.

Another optional component of the liquid loop cooling system 314 is a liquid-to-air heat exchanger 320 that can be coupled to the tubing 306. A further optional component is a reservoir 322 that can be coupled to the tubing for accumulating cooling fluid.

Liquid loop cooling 314 may be used in various applications for the thermal management of electronics resulting from increasing power densities in power electronics, defense, medical, and computer applications. Liquid loop cooling 314 is increasingly useful for high-end servers, storage systems, telecommunication equipment, automatic test equipment, and the like as a result of enhancements in power densities and reduction packaging size.

Liquid loop cooling systems use closed-loop circulation of a coolant and may include flow distribution components such as tubes and pumps, flow control devices including valves and orifices, and heat transfer devices such as cold plates and heat exchangers. The designs of liquid loop cooling systems are generally arranged to create and distribute a sufficient total flow to maintain electronic component temperature at a suitable level.

The liquid loop cooling system 314 is generally designed by sizing individual components so that a desired coolant flow is delivered to the cold plates 316 and/or heat sinks to which electronic devices and components are mounted. The cold plates 316 and/or heat sinks are selected to attain effective and uniform cooling.

A designer may arrange the liquid loop cooling system 314 in the electronic system 300 by distributing one or more electronic system components 304, including at least one heat-generating component, in the chassis 302. The rigid or semi-rigid tubing 306, which encloses an interior bore, circulates the cooling fluid among the one or more heat-generating components in the closed-loop system. At least one flexible bellows 308 is attached to the tubing 306, thereby isolating physical stresses along the tubing 306.

The flexible bellows 308 can be coupled between two components 304 to reduce physical stress along the tubing 306. For example, the flexible bellows 308 can be positioned along the tubing 306 between a component 304 and a potential source of shock and vibration, such as a heavy device coupled to a line. In a particular example, a pump 318, a heat exchanger 320, or a reservoir 322 can be relatively heavy and bulky. A board containing a heavy, bulky element, upon dropping or shaking, can generate stresses along the tubing 306 that can potentially damage fragile components. The flexible bellows 308 absorbs the forces, facilitating component and system protection.

The flexible bellows 308 may be positioned along the tubing 306 between rigidly-attached components 304 to accommodate expansion and contraction due to temperature changes. Similarly, the flexible bellows 308 can be positioned along the tubing 306 between rigidly-attached components 304 to accommodate dimensional variation due to manufacturing tolerances.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, although particular shapes, sizes, and geometries of the bellows are shown, other arrangements are possible. Also, particular electronic system embodiments are illustrated, for example a computer server. In other embodiments, the bellows can be employed in other types of electronic systems such as communication systems, storage systems, entertainment systems, and the like.

1. A liquid loop cooling apparatus comprising:
a rigid or semi-rigid tubing enclosing an interior bore within which a cooling fluid can circulate among at least one heat-generating component in a closed-loop system; and
at least one flexible bellows coupled to the tubing and isolating physical stresses along the tubing.

2. The cooling apparatus according to claim 1 further comprising:
at least one cold plate coupled to the tubing.

3. The cooling apparatus according to claim 1 further comprising:
a pump coupled to the tubing and capable of circulating the cooling fluid through the liquid loop.

4. The cooling apparatus according to claim 1 further comprising:
a liquid-to-air heat exchanger coupled to the tubing.

5. The cooling apparatus according to claim 1 further comprising:
a reservoir coupled to the tubing and capable of accumulating cooling fluid.

6. The apparatus according to claim 1 wherein:
at least one component is rigidly coupled to the tubing; and
the at least one flexible bellows flexibly mechanically isolates parts of the rigid or semi-rigid liquid loop cooling apparatus from the other parts.

7. A computer server comprising:
a chassis;
a plurality of components mounted within the chassis including at least one heat-generating component;
a rigid or semi-rigid tubing enclosing an interior bore within which a cooling fluid can circulate among the at least one heat-generating component in a closed-loop system; and
at least one flexible bellows coupled to the tubing and isolating physical stresses along the tubing.

8. The server according to claim 7 further comprising:
airflow inlet and outlet vents in the chassis; and
at least one fan capable of circulating air from the inlet vents to the outlet vents.

9. The server according to claim 7 further comprising:
at least one cold plate coupled to the tubing and arranged to dissipate heat from a heat-generating component.

10. The server according to claim 7 further comprising:
a pump coupled to the tubing and capable of circulating the cooling fluid through the liquid loop.

11. The server according to claim 7 further comprising:
a liquid-to-air heat exchanger coupled to the tubing.

12. The server according to claim 7 further comprising:
a reservoir coupled to the tubing and capable of accumulating cooling fluid.

13. The server according to claim 7 further comprising:
at least one component is rigidly coupled to the tubing; and
the at least one flexible bellows flexibly mechanically isolates parts of the rigid or semi-rigid liquid loop cooling apparatus from the other parts.

14. The server according to claim 7 wherein:
the chassis is a compact form factor chassis.

15. A method of arranging a liquid loop cooling system in an electronic system comprising:
distributing a plurality of electronic system components including at least one heat-generating component in a chassis;
arranging a rigid or semi-rigid tubing enclosing an interior bore within which a cooling fluid can circulate among the at least one heat-generating component in a closed-loop system; and
connecting at least one flexible bellows to the tubing thereby isolating physical stresses along the tubing.

16. The method according to claim 15 further comprising:
positioning a flexible bellows along the tubing between a component and a potential source of shock and vibration.

17. The method according to claim 15 further comprising:
positioning a flexible bellows along the tubing between rigidly-attached components to accommodate expansion and contraction due to temperature changes.

18. The method according to claim 15 further comprising:
positioning a flexible bellows along the tubing between rigidly-attached components to accommodate dimensional variation due to manufacturing tolerances.

19. The method according to claim 15 further comprising:
coupling a flexible bellows between two components to reduce physical stress along the tubing.

20. A liquid loop cooling apparatus comprising:
means for carrying a circulating cooling fluid among at least one heat-generating component in a closed-loop system; and
means for isolating physical stresses along the carrying means.
